(19) United States
(12) Patent Application Publication
(10) Pub. No.: US 2026/0304808 A1
(43) Pub. Date: Oct. 1, 2026

(54) BIPOLAR JUNCTION TRANSISTORS WITH NANOSHEET STRUCTURES AND METHODS FOR MANUFACTURING THE SAME

(71) Applicant: Tokyo Electron Limited, Tokyo (JP)

(72) Inventors: Alan SHAFI, Albany, NY (US); Jeffrey SMITH, Albany, NY (US); H. Jim FULFORD, Marianna, FL (US)

(73) Assignee: Tokyo Electron Limited, Tokyo (JP)

(21) Appl. No.: 19/094,354

(22) Filed: Mar. 28, 2025

(51) Int. Cl. H10D 10/60; H10D 10/01; H10D 30/00; H10D 30/01; H10D 30/43; H10D 62/10; H10D 62/13; H10D 62/60; H10D 62/83; H10D 62/832; H10D 84/01; H10D 84/40

(52) U.S. Cl. CPC H10D 10/60; H10D 10/061; H10D 30/014; H10D 30/0191; H10D 62/121; H10D 62/134; H10D 62/137; H10D 62/60; H10D 62/83; H10D 62/832; H10D 84/0107; H10D 30/43; H10D 30/502; H10D 84/401

(57) ABSTRACT

One aspect of the present disclosure is directed to a semiconductor device. The semiconductor device includes a plurality of stacks protruding from a substrate, wherein each of the plurality of stacks extends in a first lateral direction and includes a plurality of first semiconductor layers and a plurality of second semiconductor layers alternately stacked on top of one another. The semiconductor device includes an emitter structure having a first conductivity and extending along a second lateral direction to traverse a first subset of the plurality of stacks. The semiconductor device includes a first collector structure having the first conductivity and extending along the second lateral direction to traverse a second subset of the plurality of stacks. The semiconductor device includes a first base structure having a second conductivity and extending along the second lateral direction to traverse a third subset of the plurality of stacks.

### FIELD OF THE DISCLOSURE

This disclosure relates to microelectronic devices including semiconductor devices, transistors, and integrated circuits, including methods of microfabrication.

### BACKGROUND

For a number of reasons that include reduction of semiconductor size, field effect transistors (FETs) fabricated with complementary metal oxide semiconductor (CMOS) technology have become standard for integrated circuits where a large number of semiconductor devices are packed onto a chip. Use of CMOS technology has generally allowed a reduction of semiconductor device size from that achieved using bipolar junction transistors (BJTs).

One of the goals of the semiconductor industry is to continue shrinking the size and increasing the speed of individual transistors. To achieve these goals, non-planar transistor structures have been used in advanced technology nodes. For example, gate-all-around (GAA) transistor structures not only improve areal density in the same layout area (when compared to the traditional planar transistor structures) but also improve gate control of the channel. Stated another way, GAA transistor structures boost the performance and reduce leakage (power consumption) of transistors.

### SUMMARY

BJTs and GAA transistors require different structures. Therefore, they are typically fabricated using different fabrication processes. The present disclosure will be described in context of forming a BJT using a GAA transistor-based process flow. The BJT, as disclosed herein, is compatible to the current GAA transistor process flow. The present disclosure may also be applied, however, to other types of semiconductor device structures or circuits. (e.g., diode, resistor, well pickup, etc.).

One aspect of the present disclosure is directed to a semiconductor device. The semiconductor device can include a plurality of stacks protruding from a substrate, wherein each of the plurality of stacks extends in a first lateral direction and can include a plurality of first semiconductor layers and a plurality of second semiconductor layers alternately stacked on top of one another. The semiconductor device can include an emitter structure having a first conductivity and extending along a second lateral direction to traverse a first subset of the plurality of stacks. The semiconductor device can include a first collector structure having the first conductivity and extending along the second lateral direction to traverse a second subset of the plurality of stacks. The semiconductor device can include a first base structure having a second conductivity and extending along the second lateral direction to traverse a third subset of the plurality of stacks.

The semiconductor device can include a second collector structure having the first conductivity and extending along the second lateral direction to traverse a fourth subset of the plurality of stacks. The semiconductor device can include a second base structure having the second conductivity and extending along the second lateral direction to traverse a fifth subset of the plurality of stacks. In some embodiments, the first and second base structures are disposed on opposite sides of the emitter structure along the first lateral direction, and the first and second collector structures are disposed on opposite sides of the emitter structure along the second lateral direction.

The semiconductor device can include a first well embedded in the substrate and having the second conductivity, wherein the first subset of stacks and the third subset of stacks are disposed over the first well. The semiconductor device can include a second well embedded in the first well and having the second conductivity, wherein the third subset of stacks are disposed over the second well; and a third well embedded in the first well and having the first conductivity, wherein the first subset of stacks is disposed over the third well. In some embodiments, the second well and the third subset of stacks have a similar doping concentration. In some embodiments, the third well and the first subset of stacks have a similar doping concentration.

In some embodiments, the first conductivity is p-type, and the second conductivity is n-type.

In some embodiments, the first conductivity is n-type, and the second conductivity is p-type.

The semiconductor device can include a first contact structure electrically connected to the emitter structure; a second contact structure electrically connected to the first base structure; and a third contact structure electrically connected to the first collector structure.

In some embodiments, each of the emitter structure, the first base structure, and the first collector structure is formed as an epitaxial structure.

Another aspect of the present disclosure is directed to a semiconductor device. The semiconductor device can include a substrate having a first conductivity; a first well embedded in the substrate and having a second conductivity; a second well embedded in the first well and having the first conductivity; a third well embedded in the first well and having the second conductivity; a first subset of stacks formed over the second well, wherein the first subset of stacks include a plurality of first semiconductor layers and a plurality of second semiconductor layers alternately stacked on top of one another, and wherein both the first and second semiconductor layers are doped with the first conductivity; a second subset of stacks formed over the substrate, wherein the second subset of stacks include a plurality of third semiconductor layers and a plurality of fourth semiconductor layers alternately stacked on top of one another, and wherein both the third and fourth semiconductor layers are doped with the first conductivity; and a third subset of stacks formed over the third well, wherein the third subset of stacks include a plurality of fifth semiconductor layers and a plurality of sixth semiconductor layers alternately stacked on top of one another, and wherein both the fifth and sixth semiconductor layers are doped with the second conductivity.

The semiconductor device can include an emitter structure disposed across the first subset of stacks; a collector structure disposed across the second subset of stacks; and a base structure disposed across the third subset of stacks.

In some embodiments, the first to sixth semiconductor layers all extend along a first lateral direction, with the emitter structure, collector structure, and base structure extending along a second lateral direction perpendicular to the first lateral direction.

In some embodiments, each of the emitter structure, collector structure, and base structure is formed as an epitaxial structure.

In some embodiments, the first, third, and fifth semiconductor layers each include silicon, and the second, fourth, and sixth semiconductor layers each include silicon germanium.

In some embodiments, the substrate and the first well operatively form a first p-n junction, and the first well and the second well operatively form a second p-n junction.

Yet another aspect of the present disclosure is directed to a method for manufacturing semiconductor devices. The method can include forming a plurality of stacks protruding from a substrate having a first conductivity, wherein each of the plurality of stacks extends in a first lateral direction and can include a plurality of first semiconductor layers and a plurality of second semiconductor layers alternately stacked on top of one another; defining a first well in the substrate that has a second conductivity, wherein the first well extends beneath a first subset of the stacks, a second subset of the stacks, and a third subset of the stacks; defining a second well in the first well that has the first conductivity, and a third well and a fourth well in the substrate, wherein the second well extends beneath the first subset of the stacks, the third well extends beneath a fourth subset of the stacks, and the fourth well extends beneath a fifth subset of the stacks; doping the second and third subsets of the stacks with the second conductivity; growing a first epitaxial structure, a second epitaxial structure, and a third epitaxial structure from the first subset of the stacks, the fourth subset of the stacks, and the fifth subset of the stacks, respectively, wherein the first to third epitaxial structures have the first conductivity; and growing a fourth epitaxial structure and a fifth epitaxial structure from the second subset of the stacks and the third subset of the stacks, respectively, wherein the fourth epitaxial structure and the fifth epitaxial structures have the second conductivity.

During the step of defining a second well, the method can include doping the first, fourth, and fifth subsets of the stacks with the first conductivity.

The first epitaxial structure can operatively serve as an emitter structure of a bipolar junction transistor, the second and third epitaxial structures can operatively serve as a collector structure of the bipolar junction transistor, and the fourth and fifth epitaxial structures can operatively serve as a base structure of the bipolar junction transistor.

Concurrently with growing the first to third epitaxial structures or growing the fourth to fifth epitaxial structures, the method may further comprise forming, from one or more of the plurality of stacks, at least a sixth epitaxial structure and a seventh epitaxial structure that operatively serve as a source structure and a drain structure of a gate-all-around transistor, respectively.

In some embodiments, the first epitaxial structure operatively serves as an emitter structure, the second and third epitaxial structures operatively serve as a collector structure, and the fourth and fifth epitaxial structures operatively serve as a base structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1A-1C show various top views of a bipolar junction transistor (BJT) structure configured with a gate-all-around (GAA) transistor structure, according to an embodiment;

FIG. 2 illustrates a flow chart of a method for fabricating a semiconductor device, according to an embodiment;

FIGS. 3A and 3B are cross-sectional views of the BJT structure in which the stacks are formed over the substrate, according to an embodiment;

FIGS. 4A and 4B are cross-sectional views of the BJT structure in which a first well is formed in the substrate, according to an embodiment;

FIGS. 5A and 5B are cross-sectional views of the BJT structure in which a second well, a fifth well, and a sixth well are formed, according to an embodiment;

FIGS. 6A and 6B are cross-sectional views of the BJT structure in which a third well and a fourth well are formed, according to an embodiment;

FIGS. 7A and 7B are cross-sectional views of the BJT structure in which a resist is applied to the entire substrate such that an SiGe structure is removed from a region to define a gate all around field effect transistor (GAA FET), according to an embodiment;

FIGS. 8A and 8B are cross-sectional views of the BJT structure in which a first epitaxial structure, a second epitaxial structure, and a third epitaxial structure are grown from various subsets of stacks, according to an embodiment;

FIGS. 9A and 9B are cross-sectional views of the BJT structure in which a plurality of contacts is formed on each structure, according to an embodiment;

FIGS. 10A and 10B are cross-sectional views of the BJT structure in which the plurality of contacts is formed on each structure, according to an embodiment; and

FIGS. 11A and 11B are cross-sectional views of the BJT structure in which the plurality of contacts is formed on each structure, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

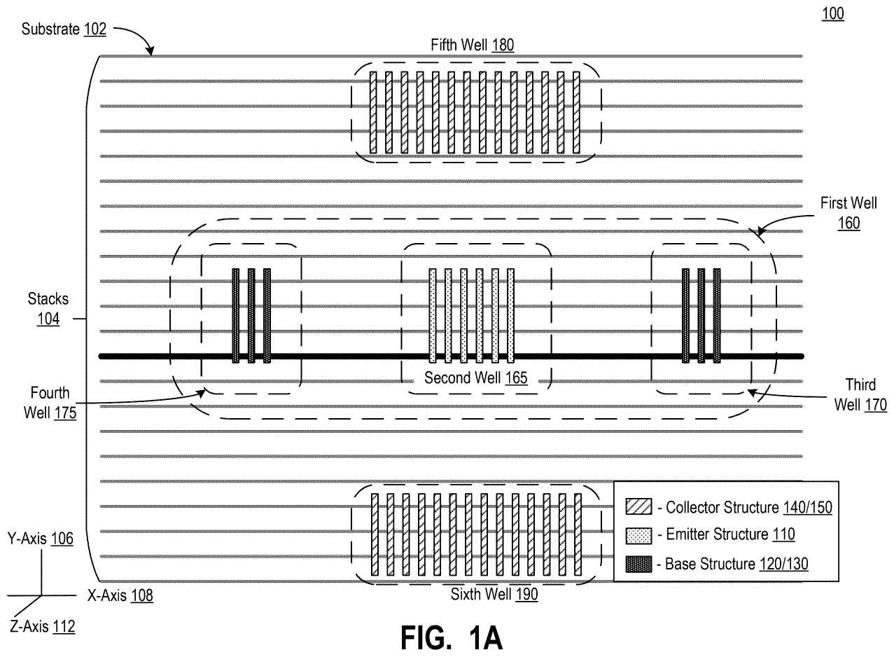

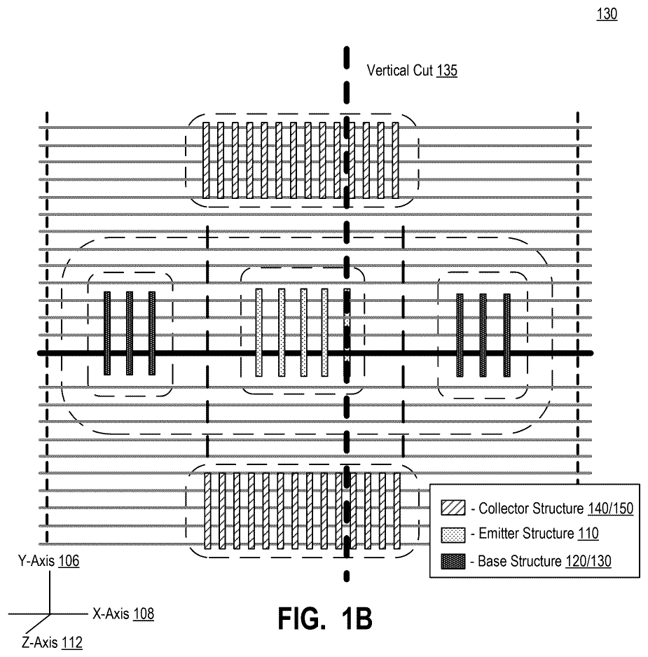

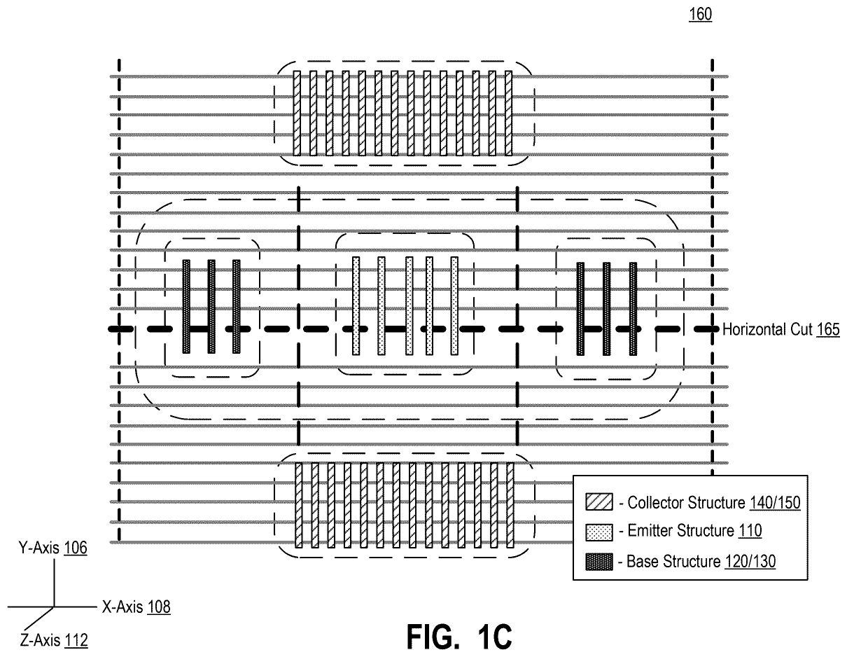

FIGS. 1A-1C show various top views of a bipolar junction transistor (BJT) structure 100 configured with a gate-all-around (GAA) transistor structure, in accordance with various embodiments. As shown, the BJT structure 100, which includes an emitter structure 110, a pair of base structures 120 and 130, and a pair of collector structures 140 and 150, is formed based on a plurality of stacks 104 over a substrate 102 having a first conductivity aligned along a Y-Axis 106, an X-axis 108, and a Z-axis 112. Optionally, a pair of base structures 120, 130 as shown in FIGS. 1A-1C, can provide a reduction in base resistance of the BJT structure 100. As another option, a pair of collector structures 140, 150, as shown in FIGS. 1A-1C, can provide a reduction in to reduce collector resistance of the BJT structure 100. In some configurations, the BJT structure 100 can include a single base structure (e.g., base structure 120 or base structure 130) and a single collector structure (e.g., collector structure 140 or collector structure 150). These stacks 104 each vertically protrude from the substrate 102 and laterally extend along a certain direction. Each of the stacks 104 includes a plurality of first semiconductor layers (sometimes referred to as first nanosheets) and a plurality of second semiconductor layers (sometimes referred to as second nanosheets) alternately stacked on top of one another, which will be shown below.

The emitter structure 110 and the collector structures 140-150 may have a first conductivity, while the base structures 120-130 may have a second conductivity. The emitter structure 110, the base structures 120-130, and the collector structures 140-150 may each be formed based on a respective subset of the stacks 104. The collector structures 140-150 can be formed in a third well 170 (having the first conductivity) and a fourth well 175 (having the first conductivity), respectively. The third to fourth wells, 170-175, can be formed or embedded in the substrate 102 outside the first well 160. Further, the emitter structure 110 and the base structures 120-130 can be formed in a first well 160 (having a second conductivity), with the emitter structure 110 and the base structures 120-130 further formed in a second well 165 (having the first conductivity), a fifth well 170 (having the second conductivity), and a sixth well 175 (having the second conductivity), respectively. The second well 165, the fifth well and the sixth well, 180-185, can be formed or embedded in the substrate 102 inside the first well 160.185185. In various embodiments of the present disclosure, fabrication of the BJT structure 100 is compatible with other CMOS-related structures (e.g., GAA transistors) formed on the same or different substrate, which can advantageously increase feasibility for fabricating the BJT structure 100. Although each well (e.g., third well 170, fourth well 175, fifth well 180, and sixth well 185) are depicted in the figures, it is appreciated that each well can be interchangeable within the scope of this disclosure. For instance, the third well 170 can be the fourth well 175, the fifth well 180, or the sixth well 185.

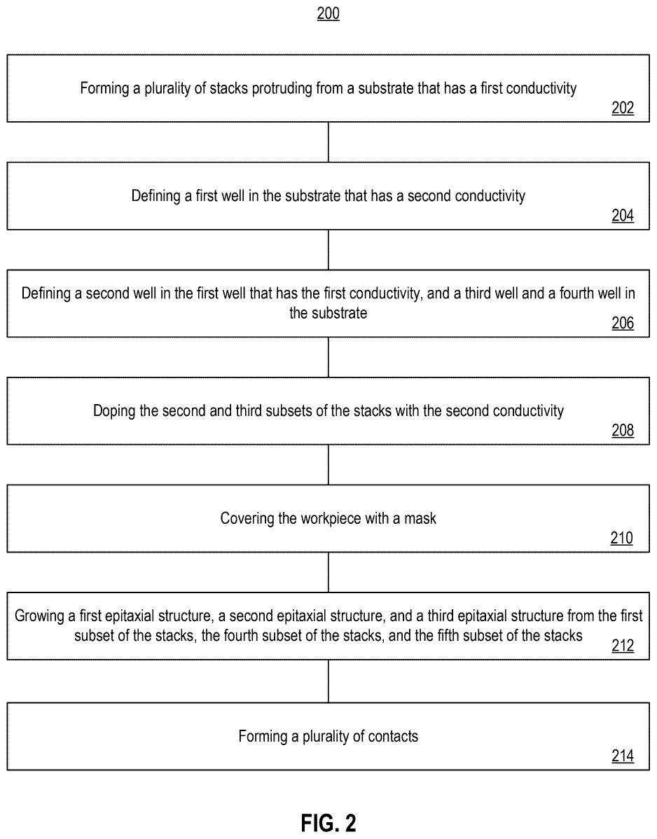

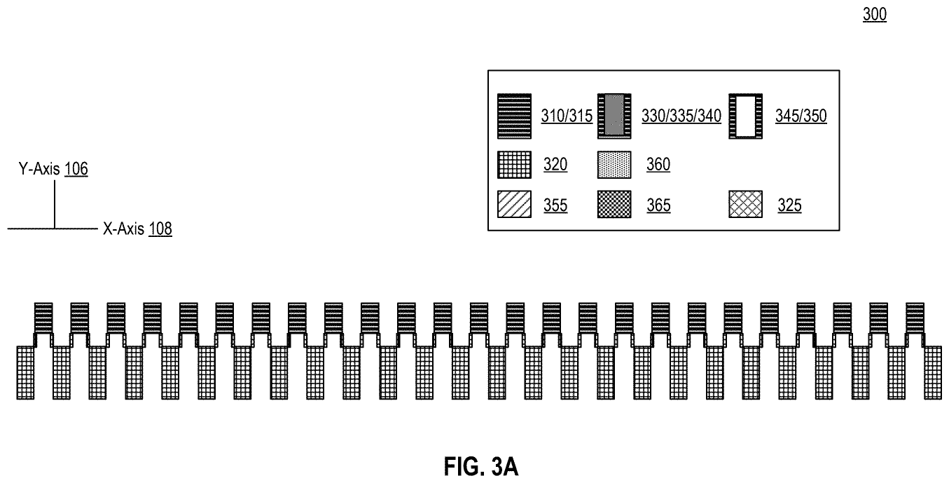

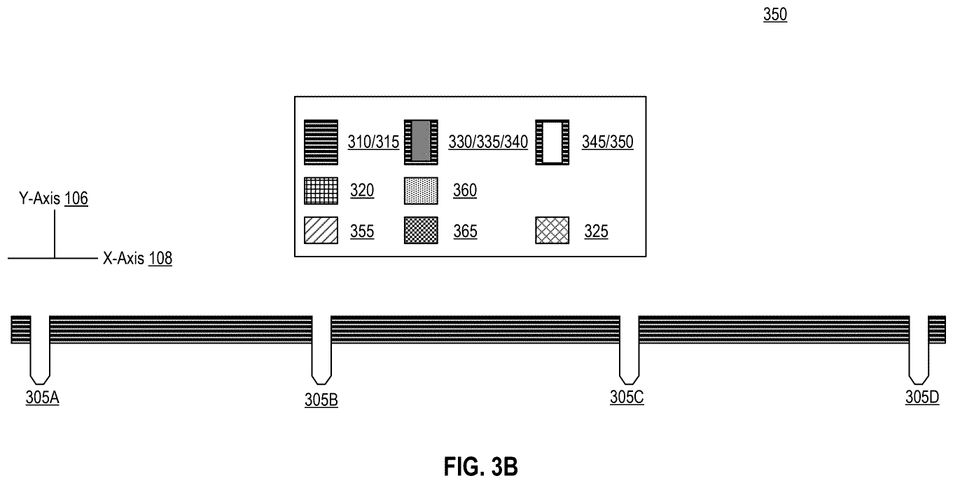

FIG. 2 illustrates a flow chart of a method 200 for fabricating or manufacturing a semiconductor device, in accordance with some embodiments. For example, the method 200 may be utilized to form the BJT structure 100 shown in FIG. 1A. It is noted that the method 200 is merely an example and is not intended to limit the present disclosure. Accordingly, it is understood that additional operations may be provided before, during, and after the method 200 of FIG. 2, that any operation may be omitted, and that some other operations may only be briefly described herein. Operations of the method 200 may be associated with cross-sectional views of example structures at various fabrication stages as shown in FIGS. 3A to 11B, which will be discussed in further detail below. It should be understood that the structure, shown in FIGS. 3A to 11B, may include a number of other structures, while remaining within the scope of the present disclosure. For example, FIGS. 3A to 11B respectively illustrate the cross-sectional views the of BJT structure 100 partially fabricated.

In brief overview, the method 200 starts with operation 202 of forming a plurality of stacks protruding from a substrate that has a first conductivity. The method 200 continues to operation 204 of defining a first well in the substrate that has a second conductivity, in which the first well extends beneath a first subset of the stacks, a second subset of the stacks, and a third subset of the stacks. The method 200 can proceed to operation 206 of defining a second well 165 in the first well that has the first conductivity, and a third well 170 and a fourth well 175 in the substrate 102, in which the second well 165 extends beneath the first subset of the stacks, the third well 170 extends beneath a fourth subset of the stacks, and the fourth well 175 extends beneath a fifth subset of the stacks. The method 200 can proceed to operation 208 of doping the second and third subsets of the stacks with the second conductivity. The method 200 can proceed to optional operation 210 of covering the workpiece with a mask. The method 200 can proceed to operation 212 of growing a first epitaxial structure, a second epitaxial structure, and a third epitaxial structure from the first subset of the stacks, the fourth subset of the stacks, and the fifth subset of the stacks, respectively, growing a fourth epitaxial structure and a fifth epitaxial structure from the second subset of the stacks and the third subset of the stacks, respectively, in which the first to third epitaxial structures have the first conductivity and the fourth and fifth epitaxial structures have the second conductivity. The method 200 can proceed to operation 214 of forming a plurality of contacts.

Corresponding to operation 202 of FIG. 2, FIGS. 3A and 3B are cross-sectional views of the BJT structure 100 in which the stacks 104 are formed over the substrate 102, respectively. Further, FIG. 3A is cut along a first lateral direction (e.g., Y-axis) perpendicular to a lengthwise direction of the stacks 104 (FIG. 1A), and FIG. 3B is cut along a second lateral direction (e.g., X-axis 108) parallel to the lengthwise direction of the stacks 104 (FIG. 1A).

In some embodiments, the substrate 102 can include a semiconductor substrate, such as a bulk semiconductor, a semiconductor-on-insulator (SOI) substrate, or the like, which may be doped (e.g., with a p-type dopant or an n-type dopant). For example, the substrate 102 may be a wafer, such as a silicon wafer. Alternatively, the semiconductor substrate 102 may include other elementary semiconductor material such as, for example, germanium. The semiconductor substrate 102 may also include a compound semiconductor such as silicon carbide, gallium arsenic, indium arsenide, and indium phosphide. The semiconductor substrate 102 may include an alloy semiconductor such as silicon germanium, silicon germanium carbide, gallium arsenic phosphide, and gallium indium phosphide.

In some embodiments, the stacks 104 can each include a number of first semiconductor layers 310 and a number of second semiconductor layers 315. The semiconductor layers 310 and 315 can be first epitaxially grown from the semiconductor substrate 102 as a bulk stack. For example, each of the semiconductor layers 310 and 315 may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the semiconductor substrate 102 extends upwardly, resulting in the semiconductor layers 310 and 315 having the same crystal orientation with the semiconductor substrate 102.

Upon the bulk stack being formed, one or more patterning processes (e.g., photolithography and etching techniques) can be performed to define the stacks 104, causing the stacks 104 to protrude from the substrate 102 and extend in parallel (or along the X-axis 108). The etching techniques can include reactive ion etch (RIE), neutral beam etch (NBE), the like, or combinations thereof. Alternatively stated, trenches can be formed between the stacks 104, each of the trenches is interposed between adjacent ones of the stacks 104. These trenches can later be partially filled with a dielectric material to form isolation structures 320, as shown in FIGS. 3A and 3B, which are each sometimes referred to as a shallow trench isolation (STI) structure. The dielectric material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. As further illustrated in FIG. 3B, upon the stacks 104 being formed, each of the stacks 104 can be cut into multiple pieces or sections (along the X-axis). These stack pieces are separated from each other by a plurality of substrate diffusion breaks (SDB) 305 extending into the substrate 102.

The first semiconductor layers 310 and the second semiconductor layers 315 are alternatingly disposed on top of one another (e.g., along the Z-axis 112) to form a corresponding one of the stacks 104. For example, one of the second semiconductor layers 315 is disposed over one of the first semiconductor layers 310 then another one of the first semiconductor layers 315 is disposed over the second semiconductor layer 310, so on and so forth.

The stack 104 may include any number of alternately disposed semiconductor layers 310 and 315. The semiconductor layers 310 and 315 may have different thicknesses. The first semiconductor layers 310 may have different thicknesses from one layer to another layer. The second semiconductor layers 315 may have different thicknesses from one layer to another layer. The thickness of each of the semiconductor layers 310 and 315 may range from few nanometers to few tens of nanometers. The first layer of the stack may be thicker than other semiconductor layers 310 and 315. In an embodiment, each of the first semiconductor layers 310 has a thickness ranging from about 3 nanometers (nm) to about 20 nm, and each of the second semiconductor layers 315 has a thickness ranging from about 3 nm to about 20 nm.

The two semiconductor layers 310 and 315 have different compositions. In various embodiments, the two semiconductor layers 310 and 315 have compositions that provide for different oxidation rates and/or different etch selectivity between the layers. In an embodiment, the semiconductor layers 310 include silicon germanium (Si₁₋ₓGeₓ), and the semiconductor layers 315 include silicon (Si). In an embodiment, each of the semiconductor layers 315 is silicon that may be undoped or substantially dopant-free (i.e., having an extrinsic dopant concentration from about 0 cm⁻³ to about 1×10¹⁷ cm⁻³), where for example, no intentional doping is performed when forming the semiconductor layers 315 (e.g., of silicon). Each well can have a similar doping concentration to a respective subset of stacks 104.

Either of the semiconductor layers 310 and 315 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the semiconductor layers 310 and 315 may be chosen based on providing differing oxidation rates and/or etch selectivity.

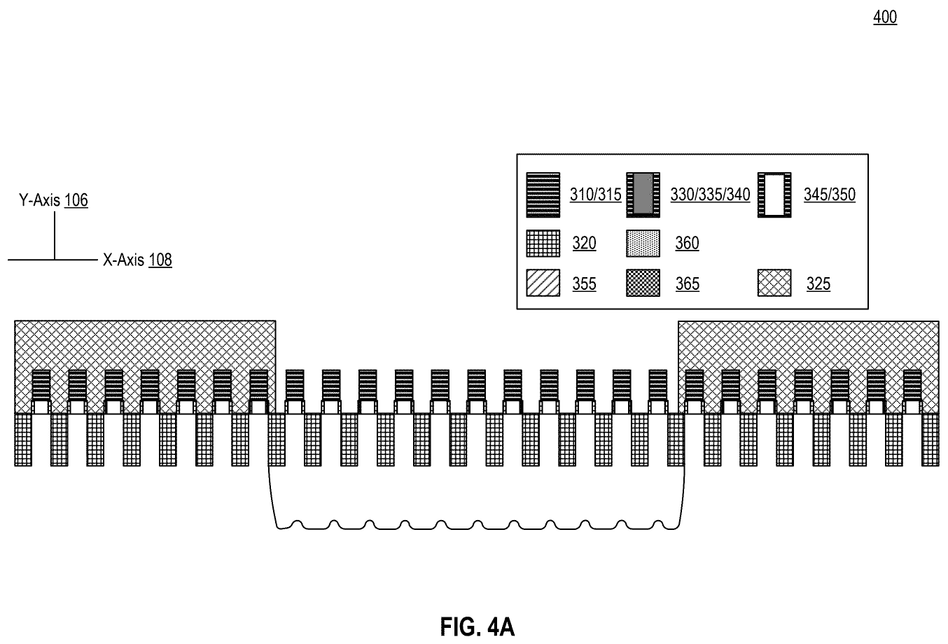

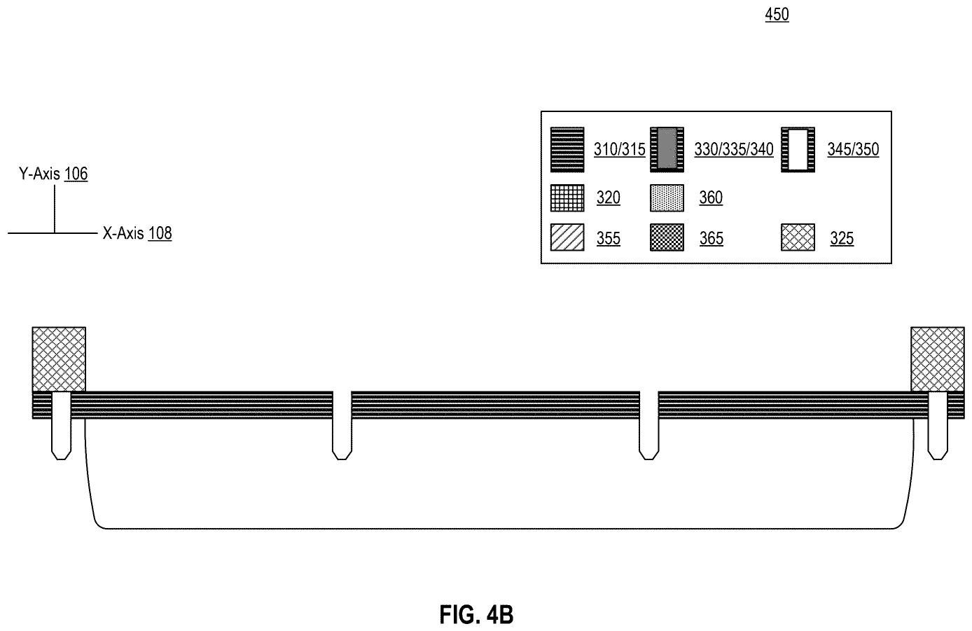

Corresponding to operation 204 of FIG. 2, FIGS. 4A and 4B are cross-sectional views of the BJT structure 100 in which the first well 160 is formed in the substrate 102, respectively. Further, FIG. 4A is cut along a first lateral direction (e.g., Y-axis 106) perpendicular to a lengthwise direction of the stacks 104 (FIG. 1A), and FIG. 4B is cut along a second lateral direction (e.g., X-axis 108) parallel to the lengthwise direction of the stacks 104 (FIG. 1A).

As shown in FIG. 4A and FIG. 4B, a resist or resist 325 (referred to as resist 325 herein) can be placed over the semiconductor layers 310 and 315 to define regions of the substrate 102 for at least one of doping, etching, or deposition, among others. In some instances, the resist 325 can cover one or more portions of the semiconductor layers 310 and 315 to allow for implantation of at least one of base structures 120 and 130, emitter structure 110, or collector structures 140 and 150. The resist 325 can include materials that are resistant to doping, etching, and deposition, while being removable to allow further processes on the semiconductor layers 310 and 315.

The first well 160 can be formed or embedded in the substrate 102 via ion implantation. The first well 160 and the substrate 102 can form a p-n junction. To implement the ion implantation, dopant atoms (e.g., boron, phosphorus, arsenic) are selected according to the type of region for the base of BJT structure 100 (e.g., n-type, p-type). For example, the base of the BJT structure 100 can be doped with arsenic or phosphors for a PNP transistor. In another example, the base of the BJT structure 100 can be boron for a NPN transistor. The first well 160 can extend beneath a first subset of the stacks 104, a second subset of the stacks 104, and a third subset of stacks 104. Each subset of stacks 104 can be separated by at least one SDB 305. For example, the first subset of stacks 104 can be separated by the first SDB 305A, whereas a second subset of stacks 104 can be separated by the second SDB 305B.

From here, the dopant atoms can be accelerated and ionized for bombardment onto the semiconductor layers 310 and 315. The dopant atoms can be bombarded onto the portion of the semiconductor layers 310 and 315 without the resist 325. In some instances, the BJT structure 100 can include undulations within the substrate due to the various thicknesses of the material of the substrate 102, amorphization, damaged crystal lattice, sputtering, surface roughening, bubble formation, among others. However, the systems and methods described herein can reduce and minimize the impact on the formation of the base of the BJT structure 100 and the function of the BJT structure 100.

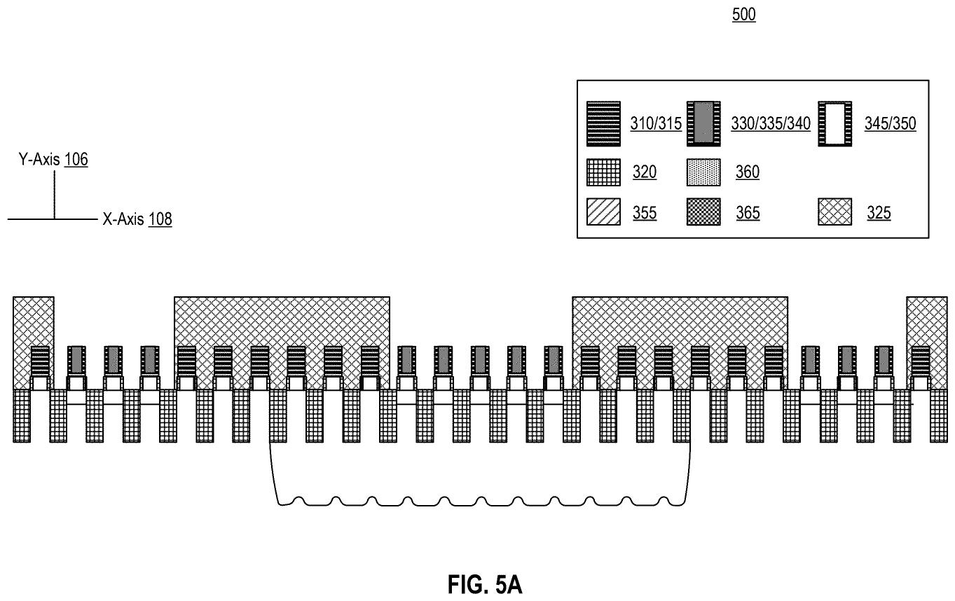

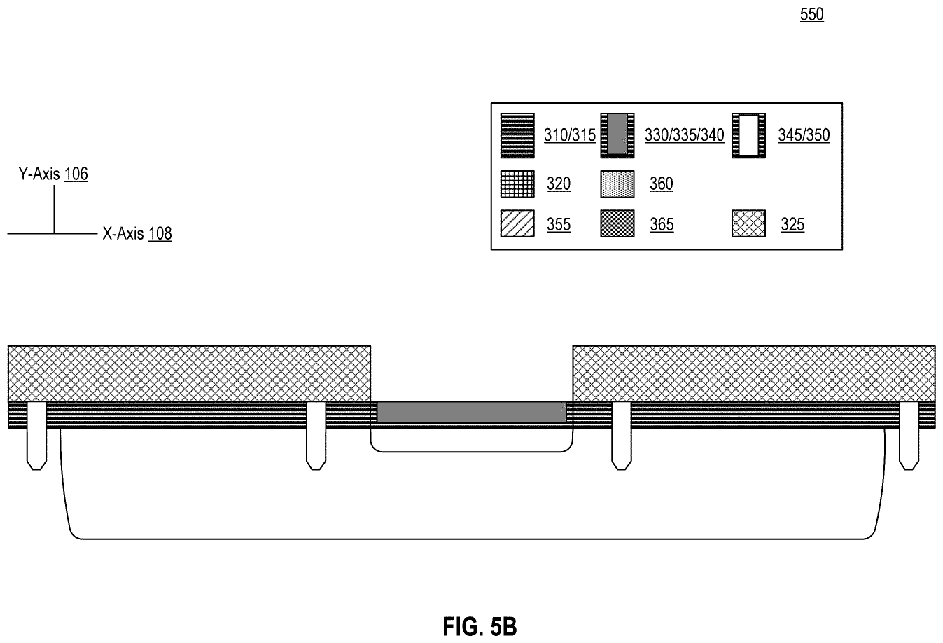

Corresponding to operation 206 of FIG. 2, FIGS. 5A and 5B are cross-sectional views of the BJT structure 100 in which the second well 165, the fifth well 180, and the sixth well 185 are formed, respectively. Further, FIG. 5A is cut along a first lateral direction (e.g., Y-axis 106) perpendicular to a lengthwise direction of the stacks 104 (FIG. 1A), and FIG. 5B is cut along a second lateral direction (e.g., X-axis 108) parallel to the lengthwise direction of the stacks 104 (FIG. 1A).

As shown in FIG. 5A and FIG. 5B, the resist 325 can be adjusted to cover the one or more portions of the substrate 102. The one or more portions can exclude the second well 165, the fifth well 180 and the sixth well 185. The first well 160 and the second well 165 can form a p-n junction. The third well 170 and the fourth well 175 can be proximal to the first well 160 along the first lateral direction (e.g., Y-axis 106). The third well 170 and the fourth well 175 can be separated by the first well 160. The third well 170 and the fourth well 175 can correspond to the collector contact regions 335 and 340 on opposite sides of the second well 165 and on distal portions of the substrate 102. As a collector contact, the regions of the substrate 102 that do not include the resist 325, can be defined as p-type regions. The third well 170 and the fourth well 175 can be defined using ion implantation to form the collector contact regions 335 and 340. In this manner, the dopant atoms can include boron and be bombarded on the substrate 102 to achieve the p-type region for the collectors of the BJT structure 100. In some instances, the dopant atoms can include gallium, aluminum, or a compound, such as boron fluoride to dope the collector contact regions 335 and 340. For instance, the collector contact regions 335 and 340 of the BJT structure 100 can be doped with boron to achieve the p-type region. In some instances, the third well 170 and the fourth well 175 can include different conductivities within the BJT structure 100. For example, the third well 170 can include a different conductivity from the fourth well 175 due to variations in at least the doping concentrations, material choice, contact formation, semiconductor type, among other factors to introduce variations. Although the third well 170 and the fourth well 175 are depicted as being doped with boron for a PNP BJT structure 100, the third well 170 and the fourth well 175 can be doped with arsenic for a NPN BJT structure 100. The fifth well 180 can extend beneath the second subset of the stacks 104. The sixth well 185 an extend below the third subset of stacks 104. Each well (e.g., second well 165, third well 170, and fourth well 175) can be separated by at least one SDB 305. Each well can be equidistant from the subsequent well according to the SDB 305. For example, the distance between the second SDB 305B and the second well 165 can be the same as the distance between the third SDB 305C and the third well 170.

The second well 165 can be centered within the first well 160 and parallel to the fifth well 180 and the sixth well 185. The second well 165 can correspond to an emitter contact region 330 central to the substrate 102. As an emitter contact, the regions of the substrate that do not include the resist 325, can be defined as p-type regions. The second well 165 can be defined using ion implantation to form the emitter contact region 330. In this manner, the dopant atoms can include boron and be bombarded on the substrate 102 to achieve the p-type region for the emitter of the BJT structure 100. In some instances, the dopant atoms can include gallium, aluminum, or a compound, such as boron fluoride to dope the emitter contact region 330. For instance, the emitter contact region 330 of the BJT structure 100 can be doped with boron to achieve the p-type region. In some instances, the second well 165 can include different conductivity than the fifth well 180, the sixth well 185, and the first well 160 within the BJT structure 100. For example, the second well 165 can include a different conductivity from the first well 160 In another example, the second well 165 can include a different conductivity from the fifth well 180 and the sixth well 185. Since the second well 165 can be centered along the first lateral direction and the second lateral direction, the emitter contact region 330 is shown in both FIG. 5A and FIG. 5B.

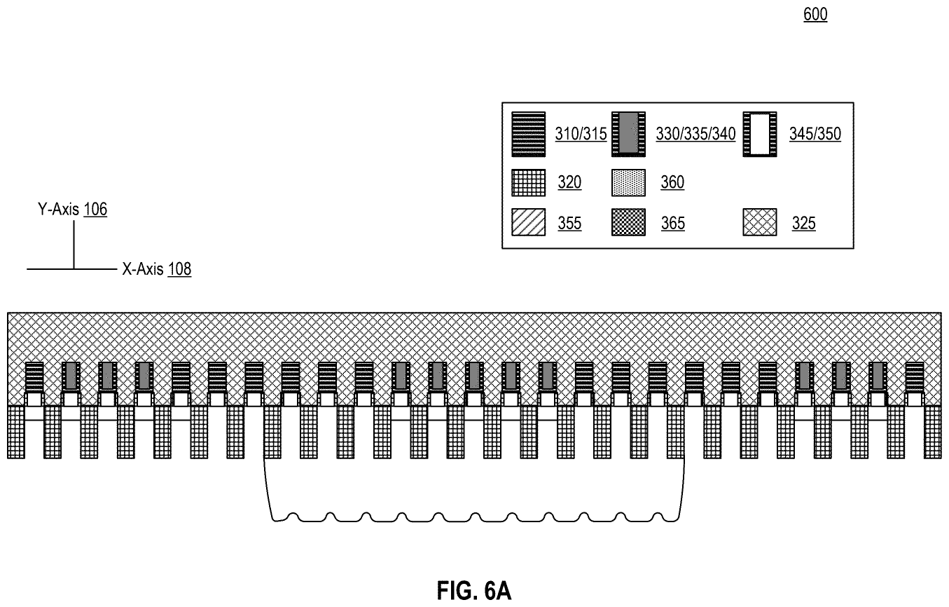

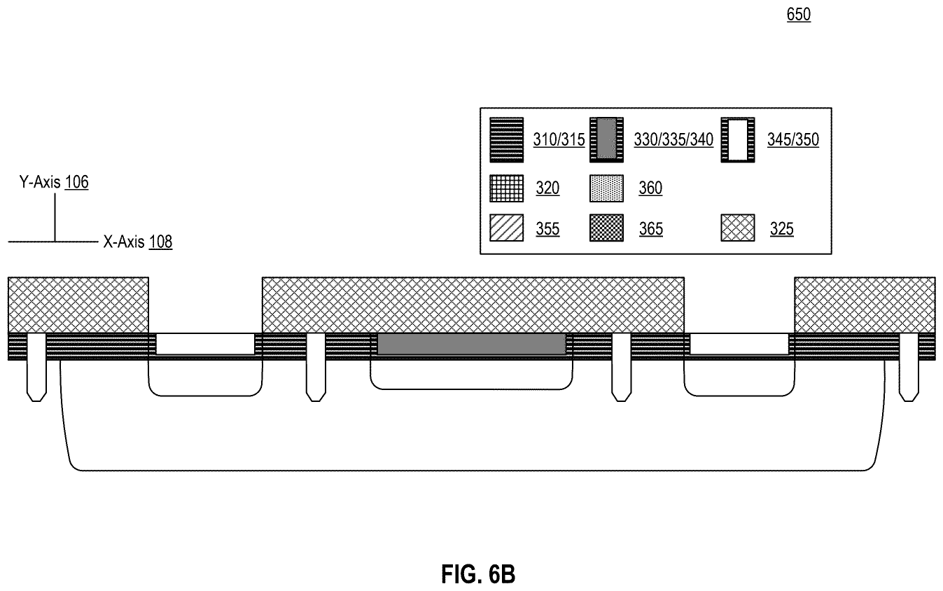

Corresponding to operation 208 of FIG. 2, FIGS. 6A and 6B are cross-sectional views of the BJT structure 100 in which the fifth well 180 and the sixth well 185 are formed, respectively. Further, FIG. 6A is cut along a first lateral direction (e.g., Y-axis 106) perpendicular to a lengthwise direction of the stacks 104 (FIG. 1A), and FIG. 6B is cut along a second lateral direction (e.g., X-axis 108) parallel to the lengthwise direction of the stacks 104 (FIG. 1A).

As shown in FIG. 6A, the resist 325 can be adjusted to cover the nanosheet or the substrate 102 along the first lateral direction. By covering the substrate 102 along the first lateral direction, the base contact regions 345 and 350 can be implanted along the second lateral direction, as shown in FIG. 6B. The resist 325 can cover the emitter structure 110 and the collector structures 140 and 150. The resist 325 can avoid one or more portions of the substrate 102 along the second lateral direction to define a region (e.g., base contact regions 345 and 350) for the third well 170 and the fourth well 175. The base contact regions 345 and 350 can be within the first well 160. The base contact regions 345 and 350 can be within the fifth well 180 and the sixth well 185, respectively. In this manner, the fifth well 180 and the sixth well 185 can be defined as n-type regions. In some instances, the fifth well 180 and the sixth well 185 can be p-type regions. The fifth well 180 and the sixth well 185 can be defined using ion implantation to form the base contact regions 345 and 350. To define the base contact regions 345 and 350 within the fifth well 180 and the sixth well 185 as an n-type region, the region for the fifth well 180 and the sixth well 185 can be bombarded with arsenic during the ion implantation. In some instances, the region of the third well 170 and the fourth well 175 can be bombarded with phosphorus during the ion implantation to define the base structures 120 and 130. The amount of doping for the base structures 120 and 130 can be higher than the amount of doping for the emitter structure 110 and the collector structure 140 and 150.

In further detail, the second well 165 can extend beneath the first subset of stack 104. The fifth well 180 can extend beneath the fourth subset of stacks 104. The sixth well 185 can extend beneath the fifth subset of stacks 104. The fifth well 180 and the sixth well 185 can be external to the first well 160 and separated from the first well 160 by the second lateral dimension. Continuing on, upon the completion of the ion implantation, the fifth well 180 and the sixth well 185 can be deposited with a layer of oxide or nitride (e.g., SiO₂ or Si₃N₄) while using etching to open contact holes at the base contact regions 345 and 350. In this manner, the fifth well 180 can include a conductivity that is different from the fifth well 185 without the presence of undulations.

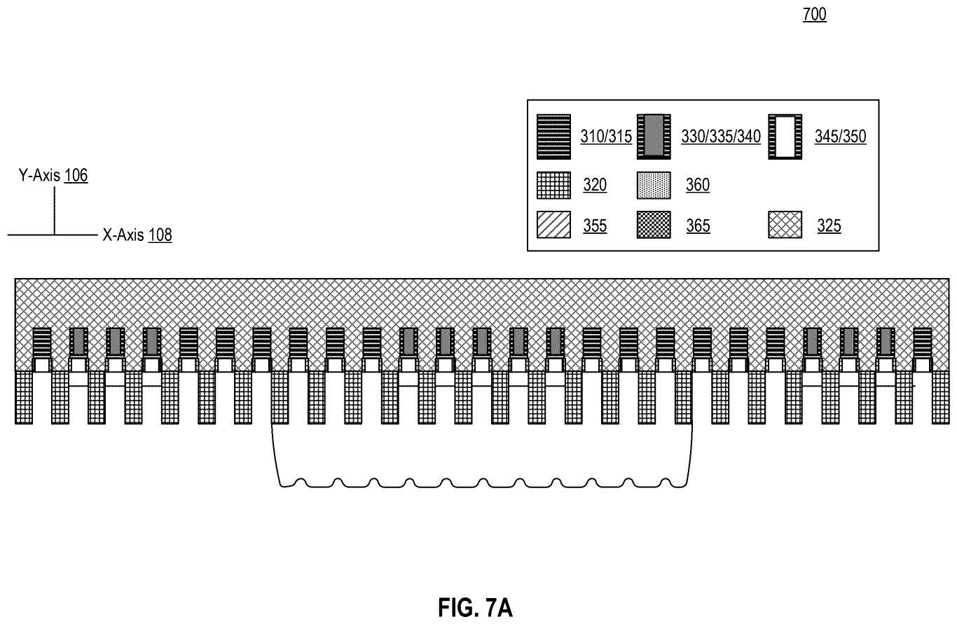

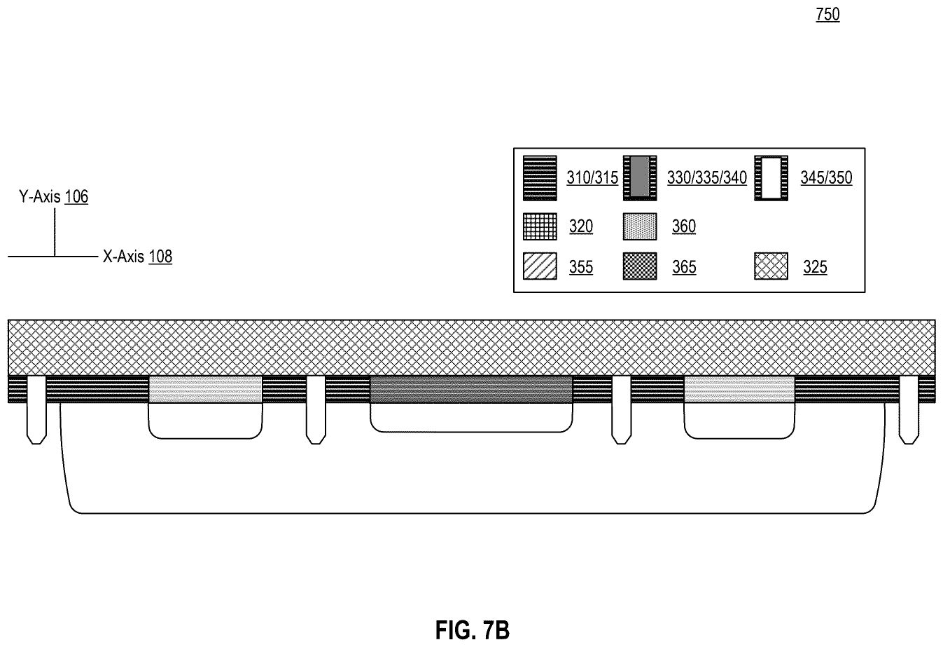

Corresponding to operation 210 of FIG. 2, FIGS. 7A and 7B are cross-sectional views of the BJT structure 100 in which the resist 325 is applied to the entire substrate 102. Further, FIG. 7A is cut along a first lateral direction (e.g., Y-axis 106) perpendicular to a lengthwise direction of the stacks 104 (FIG. 1A), and FIG. 7B is cut along a second lateral direction (e.g., X-axis 108) parallel to the lengthwise direction of the stacks 104 (FIG. 1A).

As shown in FIG. 7A and FIG. 7B, the resist 325 is applied over the entire BJT structure 100 prior to the application of the epitaxial growth. Furthermore, the silicon germanium of the semiconductor layers 310 and 315 are not removed prior to the application of the epitaxial growth to align the fabrication of the BJT structure 100 with fabrication steps included with gate-all-around (GAA) transistor fabrication. In this manner, the BJT structure 100 can include superior electrostatic control and improved power efficiency, while maintaining a higher current drive, higher transconductance, lower distortion, and higher thermal stability in comparison to other BJT structures, FinFETs, planar MOSFETs, and other GAA transistors. Furthermore, the system and methods described herein can avoid the degradation of the quality of the epitaxial layer caused from the silicon germanium by including the resist 325 over the BJT structure 100. In some instances, by maintaining the resist 325 and the silicon germanium within the BJT structure, the systems and methods described herein can improve connections between the emitter structure 110, the collector structures 140 and 150, and the base structures 120 and 130.

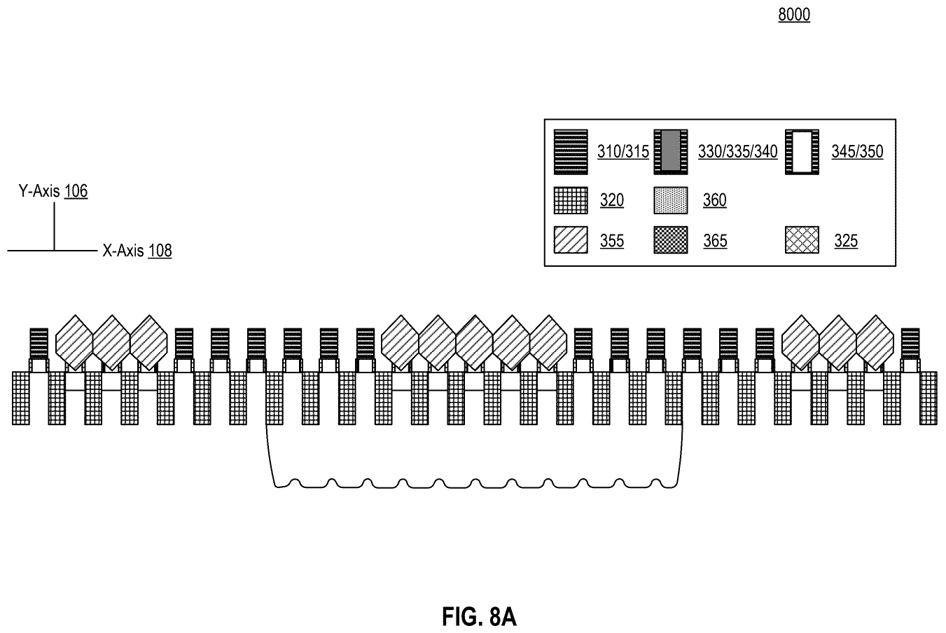

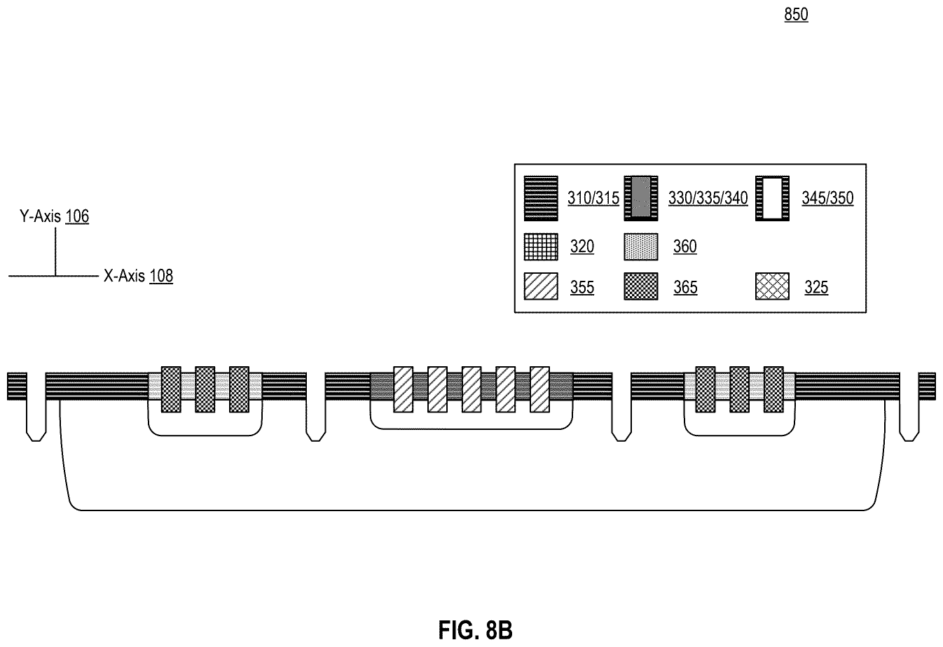

Corresponding to operation 212 of FIG. 2, FIGS. 8A and 8B are cross-sectional views of the BJT structure 100 in which a first epitaxial structure (e.g., emitter structure 110), a second epitaxial structure (e.g., collector structure 140), and a third epitaxial structure (e.g., collector structure 150) are grown from various subsets of stacks 104. Further, FIG. 8A is cut along a first lateral direction (e.g., Y-axis) perpendicular to a lengthwise direction of the stacks 104 (FIG. 1A), and FIG. 8B is cut along a second lateral direction (e.g., X-axis) parallel to the lengthwise direction of the stacks 104 (FIG. 1A). The epitaxial strictures (e.g., emitter structure 110, base structures 120 collector structure 140) can be formed concurrently or separately. For example, the emitter structure 110 and the collector structure 140, 150 can include p-type silicon prior to the growth of n-type silicon on the base structure 120, 130. In some instances, the emitter structure 110 and the collector structure 140, 150 can include n-type silicon prior to the growth of p-type silicon on the base structure 120, 130. In some embodiments, concurrently with growing the first to third epitaxial structures 110, 140, and 150, at least a pair of other epitaxial structures can be grown from one or more of the stacks 104. Such a pair of epitaxial structures can operatively serve as a source structure and a drain structure of a first GAA transistor, respectively. A conductive type of the first GAA transistor can be determined based on the conductivity type of the first to third epitaxial structures 110, 140, and 150.

To grow the second epitaxial structure (e.g., collector structure 140) and the third epitaxial structure (e.g., collector structure 150), a p-epi 355 is applied to the collector contact regions 335 and 340 to traverse the second subset of the plurality of stacks 104. Prior to the application of the p-epi 355, the resist 325 may be removed from the nanosheet or the substrate 102. Upon removal of the resist 325, the collector contact regions 335 and 340 can be cleaned via a hydrogen fluoride dip, a hydrogen bake, among other methods to prepare the surface. From here, a chemical vapor deposition (CVD) is applied at a respective temperature (e.g., 900° C.-1100° C.) to the emitter contact region 330. The epitaxy can include a single-crystal silicon epi, a silico germanium epi, a thick epi layer, among other epitaxies. Upon application of the CVD, the emitter contact region 330 can receive extra doping according to the type for the BJT structure 100 (e.g., n+ for NPE, p+ for PNP) to induce the p-epi 355 growth. The dopants can include, phosphorus or boron, among other p+ dopants. In some instances, buried layer can be applied to the collector contact regions 335 and 340 to reduce collector resistance. The buried layer can be formed from antimony, arsenic, or boron based on the type of the BJT structure 100. The collector contact regions 335 and 340 can be isolated via shallow trench isolation or local oxidation of silicon and doped to receive metal contacts 360.

Prior to the growth of the first epitaxial structure (e.g., emitter structure 110), a fourth epitaxial structure (e.g., base structure 120) and a fifth epitaxial structure (e.g., base structure 130) can be grown from the fifth subset of the stacks 104 and the third subset of the stacks 104, respectively. To grow the fourth epitaxial structure and the fifth epitaxial structure, an n-epi 365 can be applied to the base contact regions 345 and 350. In some embodiments, concurrently with growing the fourth to fifth epitaxial structures 120 and 130, at least a pair of yet other epitaxial structures can be grown from one or more of the stacks 104. Such a pair of epitaxial structures can operatively serve as a source structure and a drain structure of a second GAA transistor, respectively. A conductive type of the second GAA transistor can be determined based on the conductivity type of the fourth to fifth epitaxial structures 120 and 130.

Prior to the application of the n-epi 365, the resist 325 may be removed from the nanosheet or the substrate 102. Upon removal of the resist 325, the base contact regions 345 and 350 can be cleaned via a hydrogen fluoride dip, a hydrogen bake, among other methods to prepare the surface. From here, a chemical vapor deposition (CVD) is applied at a respective temperature (e.g., 550° C.-750° C.) to the base contact regions 345 and 350. The epitaxy can include a single-crystal silicon epi or a silico germanium epi, among other epitaxies. Upon application of the CVD, the base contact regions 345 and 350 can receive extra doping according to the type for the BJT structure 100 (e.g., n+ for NPN, p+ for PNP) to induce the n-epi 365 growth. The dopants can include, phosphorus, diborane, phosphine, boron, among other n+ dopants. In this manner, each epitaxial structure (e.g., the fourth epitaxial structure and the fifth epitaxial structure) can include the second conductivity (e.g., n-type, p-type) opposite the first conductivity.

To grow the first epitaxial structure (e.g., emitter structure 110), a p-epi 355 is applied to the emitter contact region 330 to traverse the first subset of the plurality of stacks 104. Prior to the application of the p-epi 355, the resist 325 may be removed from the nanosheet or the substrate 102. Upon removal of the resist 325, the emitter contact region 330 can be cleaned via a hydrogen fluoride dip, a hydrogen bake, among other methods to prepare the surface. From here, a chemical vapor deposition (CVD) is applied at a respective temperature (e.g., 650° C.-1100° C.) to the emitter contact region 330. The epitaxy can include a single-crystal silicon epi or a silico germanium epi, among other epitaxies. Upon application of the CVD, the emitter contact region 330 can receive extra doping according to the type for the BJT structure 100 (e.g., n+ for NPN, p+ for PNP) to induce the p-epi 355 growth. The dopants can include, phosphorus, diborane, phosphine, boron, among other p+ dopants. In some instances, an emitter cap layer can be applied to the emitter contact region 330 to reduce contact resistance and improve carrier injection. The emitter contact region 330 can be patterned and etched to allow for metallization. In this manner, each epitaxial structure (e.g., the first epitaxial structure, the second epitaxial structure, and the third epitaxial structure) can include the first conductivity (e.g., p-type, n-type) and extend along the second lateral direction.

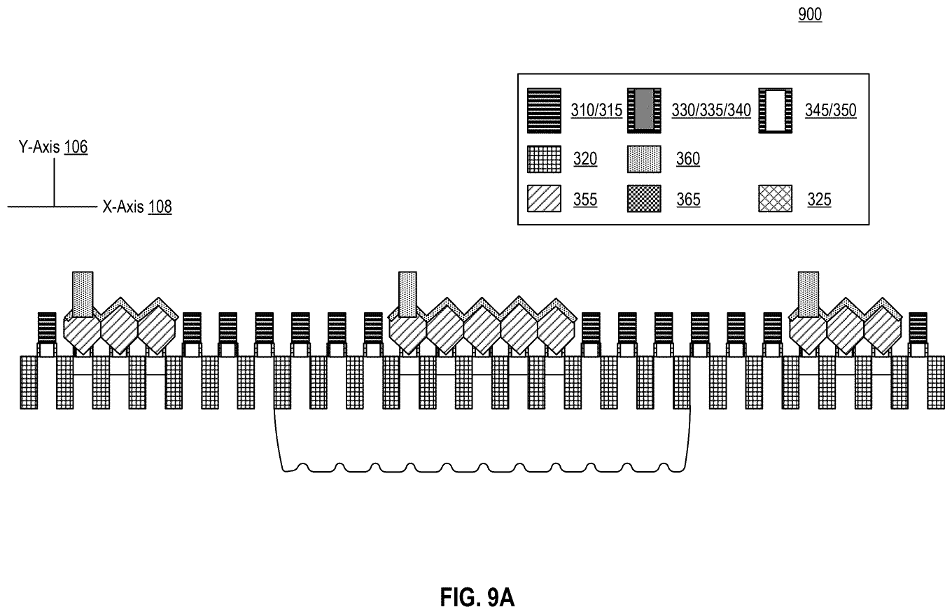

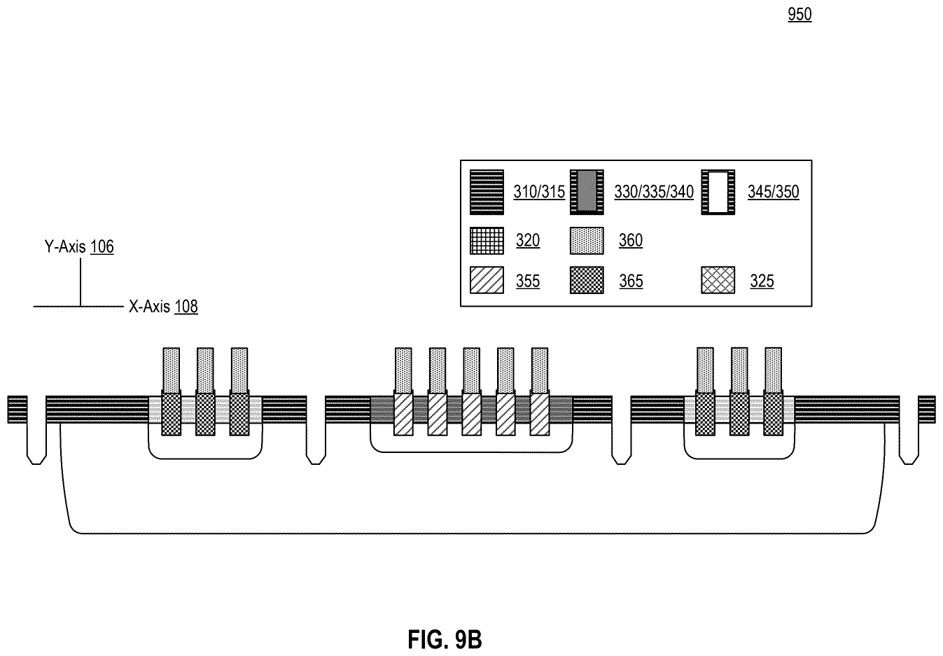

Corresponding to operation 214 of FIG. 2, FIGS. 9A and 9B are cross-sectional views of the BJT structure 100 in which a plurality of contacts 360 are formed on each structure (e.g., emitter structure 110, collector structures 140 and 150, base structures 120 and 130). FIG. 9A is cut along a first lateral direction (e.g., Y-axis) perpendicular to a lengthwise direction of the stacks 104 (FIG. 1A), and FIG. 9B is cut along a second lateral direction (e.g., X-axis) parallel to the lengthwise direction of the stacks 104 (FIG. 1A).

As shown in FIGS. 9A and 9B, the plurality of contacts 360 can be electrical connections to the various structures (e.g., emitter structure 110, collector structures 140 and 150, base structures 120 and 130) to allow or direct current to flow into and out of the BJT structure 100. The plurality of contacts 360 can be formed using metallization and various doping techniques (e.g., ion implantation, diffusion doping, in-situ doping, gas phase doping). The plurality of contacts 360 can be made of various silicides and meals optimized according to the configuration of the BJT structure 100. The silicides can include titanium silicide, cobalt silicide, nickel silicide, tungsten silicide, among other silicides and the metals can include aluminum, titanium aluminum stack, copper, tungsten, gold, platinum, among other metals. The plurality of contacts 360 can undergo silicidation or metal deposition prior to bonding wires and metal interconnects. Using the epitaxial structures (e.g., first epitaxial structure, second epitaxial structure, third epitaxial structure, fourth epitaxial structure, etc.), a metal layer can be deposited using physical vapor deposition (PVD) or CVD. Once deposited, the metal layer can be patterned and etched to define the contact pad for the collector, emitter, or the base. In some instances, silicon dioxide or silicon nitrogen can be applied to the plurality of contacts 360 for protection. The plurality of contacts 360 can be bound to an upper portion of the emitter structure 110, collector structure 140 and 150, and base structures 120 and 130 to form the BJT structure 100 as shown in FIG. 9A and FIG. 9B.

In this manner, the systems and methods described herein can use aspects of GAA technology to integrate with the formation of the BJT. By integrating the GAA with the formation of the BJT, the systems and methods described herein can incorporate benefits of the GAA development into the BJT in a seamless manner. Furthermore, the systems and methods described herein can allow for improved BJTs in a plurality of analog applications.

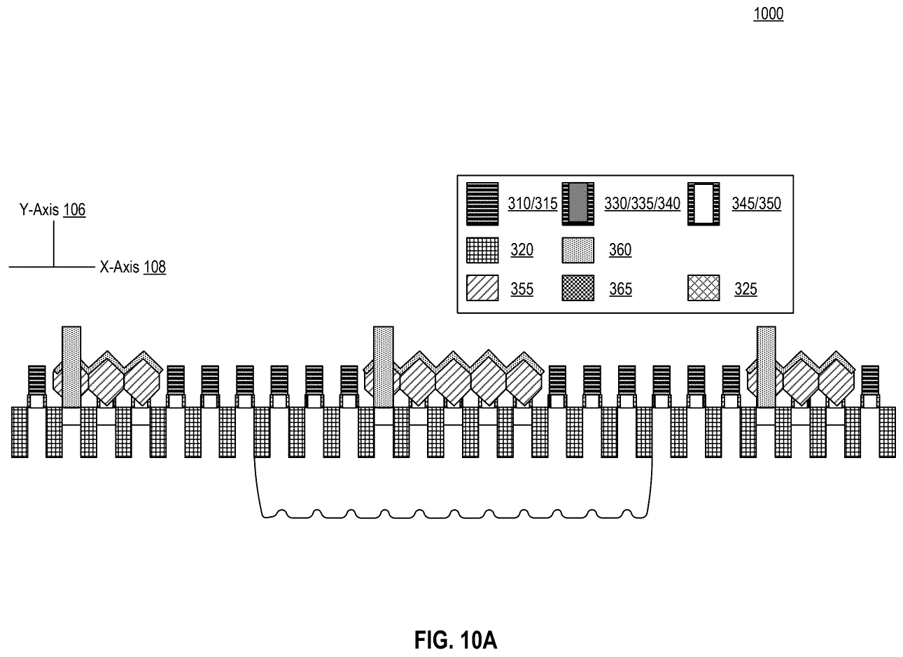

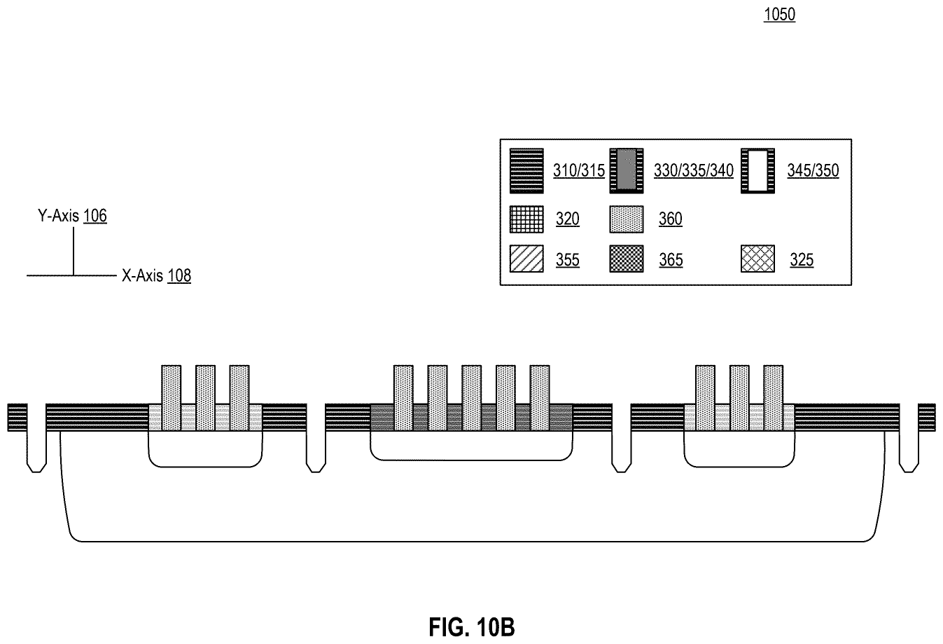

In some embodiments, as shown in FIG. 10A and FIG. 10B, FIGS. 10A and 10B are cross-sectional views of the BJT structure 100 in which the plurality of contacts 360 are formed on each structure (e.g., emitter structure 110, collector structures 140 and 150, base structures 120 and 130). Instead of the plurality of contacts 360 being bound to a portion of the emitter, base, and the collector, the plurality of contacts 360 can be etched through the p-epi and n-epi to directly contact the silicon of the emitter, collector, and base. Additional etching can be performed to separate etch the contacts 360 to land on the silicon. In this manner, the BJT structure 100 of this embodiment can include improved contact to the silicon and lower contact resistance. the BJT of this structure can be formed by, for example the method 200 of FIG. 2 and performing additional etching on the p-epi 355 and the n-epi 365.

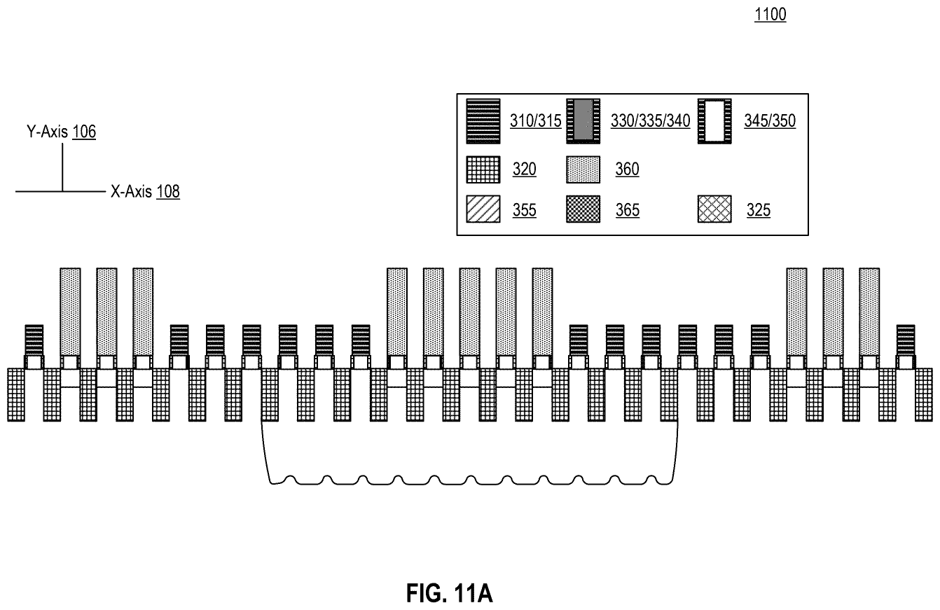

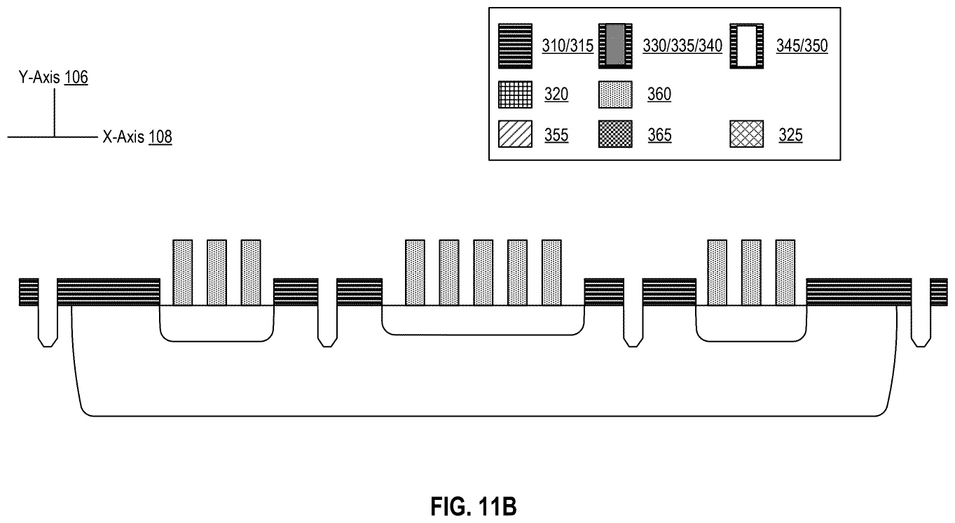

In some embodiments, as shown in FIG. 11A and FIG. 11B, FIGS. 11A and 11B are cross-sectional views of the BJT structure 100 in which the plurality of contacts 360 are formed on each structure (e.g., emitter structure 110, collector structures 140 and 150, base structures 120 and 130). The BJT structure 100 of this embodiment may not include at least some of the semiconductor layers 310 and 215, by etching the respective layers away. The plurality of contacts 360 can directly interact with the silicon substrate 102 to provide the BJT structure 100 with improved contact to the silicon and lower resistance.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a plurality of stacks protruding from a substrate, wherein each of the plurality of stacks extends in a first lateral direction and includes a plurality of first semiconductor layers and a plurality of second semiconductor layers alternately stacked on top of one another;
an emitter structure having a first conductivity and extending along the first lateral direction to traverse a first subset of the plurality of stacks;
a first collector structure having the first conductivity and extending along the first lateral direction to traverse a second subset of the plurality of stacks; and
a first base structure having a second conductivity and extending along a second lateral direction to traverse a third subset of the plurality of stacks.

2. The semiconductor device of claim 1, further comprising:
a second collector structure having the first conductivity and extending along the second lateral direction to traverse a fourth subset of the plurality of stacks; and
a second base structure having the second conductivity and extending along the second lateral direction to traverse a fifth subset of the plurality of stacks.

3. The semiconductor device of claim 2, wherein the first and second base structures are disposed on opposite sides of the emitter structure along the first lateral direction, and the first and second collector structures are disposed on opposite sides of the emitter structure along the second lateral direction.

4. The semiconductor device of claim 1, further comprising:
a first well embedded in the substrate and having the second conductivity, wherein the first subset of stacks and the third subset of stacks are disposed over the first well.

5. The semiconductor device of claim 4, further comprising:
a second well embedded in the first well and having the second conductivity, wherein the third subset of stacks are disposed over the second well; and
a third well embedded in the first well and having the first conductivity, wherein the first subset of stacks is disposed over the third well.

6. The semiconductor device of claim 5, wherein the second well and the third subset of stacks have a similar doping concentration.

7. The semiconductor device of claim 5, wherein the third well and the first subset of stacks have a similar doping concentration.

8. The semiconductor device of claim 1, wherein the first conductivity is p-type, and the second conductivity is n-type.

9. The semiconductor device of claim 1, wherein the first conductivity is n-type, and the second conductivity is p-type.

10. The semiconductor device of claim 1, further comprising:
a first contact structure electrically connected to the emitter structure;
a second contact structure electrically connected to the first base structure; and
a third contact structure electrically connected to the first collector structure.

11. The semiconductor device of claim 1, wherein each of the emitter structure, the first base structure, and the first collector structure is formed as an epitaxial structure.

12. A semiconductor device, comprising:
a substrate having a first conductivity;
a first well embedded in the substrate and having a second conductivity;
a second well embedded in the first well and having the first conductivity;
a third well embedded in the first well and having the second conductivity;
a first subset of stacks formed over the second well, wherein the first subset of stacks includes a plurality of first semiconductor layers and a plurality of second semiconductor layers alternately stacked on top of one another, and wherein both the first and second semiconductor layers are doped with the first conductivity;
a second subset of stacks formed over the substrate, wherein the second subset of stacks include a plurality of third semiconductor layers and a plurality of fourth semiconductor layers alternately stacked on top of one another, and wherein both the third and fourth semiconductor layers are doped with the first conductivity; and
a third subset of stacks formed over the third well, wherein the third subset of stacks include a plurality of fifth semiconductor layers and a plurality of sixth semiconductor layers alternately stacked on top of one another, and wherein both the fifth and sixth semiconductor layers are doped with the second conductivity.

13. The semiconductor device of claim 12, further comprising:
an emitter structure disposed across the first subset of stacks;
a collector structure disposed across the second subset of stacks; and
a base structure disposed across the third subset of stacks.

14. The semiconductor device of claim 13, wherein the first to sixth semiconductor layers all extend along a first lateral direction, with the emitter structure, collector structure, and base structure extending along a second lateral direction perpendicular to the first lateral direction.

15. The semiconductor device of claim 13, wherein each of the emitter structure, collector structure, and base structure is formed as an epitaxial structure.

16. The semiconductor device of claim 12, wherein the first, third, and fifth semiconductor layers each include silicon, and the second, fourth, and sixth semiconductor layers each include silicon germanium.

17. The semiconductor device of claim 12, wherein the substrate and the first well operatively form a first p-n junction, and the first well and the second well operatively form a second p-n junction.

18. A method for manufacturing semiconductor devices, comprising:
forming a plurality of stacks protruding from a substrate that has a first conductivity, wherein each of the plurality of stacks extends in a first lateral direction and includes a plurality of first semiconductor layers and a plurality of second semiconductor layers alternately stacked on top of one another;
defining a first well in the substrate that has a second conductivity, wherein the first well extends beneath a first subset of the stacks, a second subset of the stacks, and a third subset of the stacks;
defining a second well in the first well that has the first conductivity, and a third well and a fourth well in the substrate, wherein the second well extends beneath the first subset of the stacks, the third well extends beneath a fourth subset of the stacks, and the fourth well extends beneath a fifth subset of the stacks;
growing a first epitaxial structure, a second epitaxial structure, and a third epitaxial structure from the first subset of stacks, the fourth subset of stacks, and the fifth subset of stacks, respectively, wherein the first epitaxial structure, the second epitaxial structure, and the third epitaxial structure have the first conductivity; and
growing a fourth epitaxial structure and a fifth epitaxial structure from the second subset of the stacks and the third subset of the stacks, respectively, wherein the fourth epitaxial structure and the fifth epitaxial structure have the second conductivity.

19. The method of claim 18, wherein the first epitaxial structure operatively serves as an emitter structure of a bipolar junction transistor, the second and third epitaxial structures operatively serve as a collector structure of the bipolar junction transistor, and the fourth and fifth epitaxial structures operatively serve as a base structure of the bipolar junction transistor.

20. The method of claim 19, concurrently with growing the first to third epitaxial structures or growing the fourth to fifth epitaxial structures, further comprising:
forming, from one or more of the plurality of stacks, at least a sixth epitaxial structure and a seventh epitaxial structure that operatively serve as a source structure and a drain structure of a gate-all-around transistor, respectively.
